(19) United States
(12) Patent Application Publication
(10) Pub. No.: US 2011/0223768 A1
(43) Pub. Date: Sep. 15, 2011

(54) Method for Forming Contact Opening

(75) Inventors: Ying-Chih LIN, Tainan City (TW); Pei-Yu Chou, Anding Township (TW); Jiunn-Hsiung Liao, Shanhua Township (TW); Feng-Yi Chang, Puzi City (TW); Chih-Wen Feng, Shanhua Township (TW); Shang-Yuan Tsai, Kaohsiung City (TW)

(73) Assignee: UNITED MICROELECTRONICS CORP.

(21) Appl. No.: 12/720,671

(22) Filed: Mar. 10, 2010

(51) Int. Cl. H01L 21/311

(52) U.S. Cl. 438/700; 257/E21.249

(57) ABSTRACT

A method for forming contact openings is provided. First, a semiconductor device is formed on a substrate. Next, an etching stop layer, a first dielectric layer and a patterned photoresist layer are sequentially formed on the substrate. Next a portion of the first dielectric layer and a portion of the etching stop layer are removed to form an opening, wherein the portion of the first dielectric layer and the portion of the etching stop layer are not covered by the patterned photoresist layer. Next, the patterned photoresist layer is removed. Next, an over etching process is performed to remove the etching stop layer at a bottom of the opening and expose the semiconductor device in a nitrogen-free environment. The reactant gas of the over etching process includes fluorine-containing hydrocarbons, hydrogen gas and argon gas.

### BACKGROUND

1. Field of the Invention

The present invention relates to a semiconductor fabrication process, and more particularly to a method for forming contact opening.

2. Description of the Related Art

Recently, in a semiconductor fabrication process, after transistors are formed on a substrate, a silicon nitride layer should be formed to cover the whole substrate. In a process of forming a contact window, the silicon nitride layer is used as an etching stop layer (or named as contact etching stop layer, CESL). Stress generated by the contact etching stop layer may increase mobility of electron and electron hole in the substrate, thereby improving performance of the device.

Generally, if a size of an integrated circuit component is continuously getting smaller, some challenges may be encountered during an etching process for the contact window.

FIGS. 1A to 1C are cross-sectional schematic views of a contact opening at stages in a conventional manufacturing process.

Referring to FIG. 1A, first, a substrate 100 is provided. The substrate 100 has a shallow trench isolation structure 101 formed therein. Next, a plurality of transistors 102 are formed on the substrate 100. Each of the transistors 102 includes a gate 104, a source/drain region 106, a spacer 108 and a metal silicide layer 110. Next, a contact etching stop layer 112, an interlevel dielectric layer 114 and a patterned photoresist layer 116 are sequentially formed on the substrate 100. Material of the contact etching stop layer 112 is silicon nitride. Material of the interlevel dielectric layer 114 is silicon oxide. Because integration of the device is increased, a merge phenomenon may arise in the contact etching stop layer 112 between the transistors 102, and thus a gap would be formed in the merge position, as shown in region 111.

Next, referring to FIG. 1B, a dry etching process is performed by using the patterned photoresist layer 116 as a mask remove a portion of the interlevel dielectric layer 114 and a portion of the contact etching stop layer 112, so as to form a contact opening 118. Because of the merge phenomenon arising in the contact etching stop layer 112 between the transistors 102, a problem of incomplete etching may easily arise. Consequently, a portion of the contact etching stop layer 112 and a portion of interlevel dielectric layer 114 would be remained at a bottom of the contact opening 118, and thus a yield rate and reliability of the device would be adversely affected.

Next, referring to FIG. 1C, to ensure stability of a subsequent process, an over etching process 120 is performed to remove the layers completely that are remained at the bottom of the contact opening 118, after removing the patterned photoresist layer 116. A reactant gas of the over etching process 120 mainly includes methyl fluoride (CH₃F). In order to remove polymer by-products, the reactant gas should include oxygen gas (O₂).

However, a speed of the over etching process 120 is unduly fast while the reactant gas include the oxygen gas to remove the polymer by-products. Therefore, the spacer 108 and the shallow trench isolation structure 101 may be easily damaged during the process of the over etching process 120, and a problem that the metal silicide layer 110 is removed arises. Consequently, leakage of the device may occur to reduce the reliability of the device dramatically. Furthermore, the metal silicide layer 110 may be oxidized by the oxygen gas to make electric property of the contact window be uncontrollable.

What is needed, therefore, is a new method for forming contact opening that can overcome the above-mentioned shortcomings.

### BRIEF SUMMARY

The present invention relates to a method for forming contact opening, which may prevent a semiconductor device and an isolation structure from being removed or damaged to affect reliability of fabrication process.

The present invention provides a method for forming contact opening. The method includes the following steps. First, a semiconductor device is formed on a substrate. Next, an etching stop layer, a first dielectric layer and a patterned photoresist layer are sequentially formed on the substrate. Next a portion of the first dielectric layer and a portion of the etching stop layer are removed to form an opening, wherein the portion of the first dielectric layer and the portion of the etching stop layer are not covered by the patterned photoresist layer. Next, the patterned photoresist layer is removed. Next, an over etching process is performed to remove the etching stop layer at a bottom of the opening and expose the semiconductor device in a nitrogen-free environment. The reactant gas of the over etching process includes fluorine-containing hydrocarbons, hydrogen gas and argon gas.

In one embodiment, the fluorine-containing hydrocarbons is selected from the group consisting of carbon tetrafluoride, fluoroform, difluoromethane, methyl fluoride and any combination thereof.

In one embodiment, a surface treatment process is further performed to clean the opening by using a mixed gas, after performing the over etching process. The mixed gas can include nitrogen gas and hydrogen gas. In the mixed gas, a flow rate of the nitrogen gas can be larger than that of the hydrogen gas. In addition, a time used in the surface treatment process can be 1 to 1.5 times of that used in the over etching process.

In one embodiment, after removing the patterned photoresist layer and before performing the over etching process, a pre-etching process is further performed in the nitrogen-free environment. A reactant gas of the pre-etching process includes fluorine-containing hydrocarbons, oxygen gas and argon gas. The fluorine-containing hydrocarbons can be selected from the group consisting of carbon tetrafluoride, fluoroform, difluoromethane, methyl fluoride and any combination thereof.

In one embodiment, a second dielectric layer is formed on the first dielectric layer, before forming the patterned photoresist layer. Material of the second dielectric layer can include silicon oxynitride.

In one embodiment, material of the etching stop layer includes silicon nitride.

In the above method for forming contact opening of the present invention, a speed of removing the polymer by-products by the hydrogen gas is smaller than that by the oxygen gas. Therefore, when the layers at the bottom of the opening are removed, a small quantity of the polymer by-products may be remained to protect the bottom of the opening, so as to make etching rate be uniform. As such, the structures of the semiconductor device or the isolation structure can be prevented from being removed or damaged. In addition, the metal silicide layer would not be oxidized, and thus the problem that a yield rate and reliability of the device are adversely affected can be avoided.

### BRIEF DESCRIPTION OF THE DRAWINGS

These and other features and advantages of the various embodiments disclosed herein will be better understood with respect to the following description and drawings, in which like numbers refer to like parts throughout, and in which:

FIGS. 1A to 1C are cross-sectional schematic views of a contact opening at stages in a conventional manufacturing process.

FIGS. 2A to 2F are cross-sectional schematic views of a contact opening at stages in a manufacturing process according to an embodiment of the present invention.

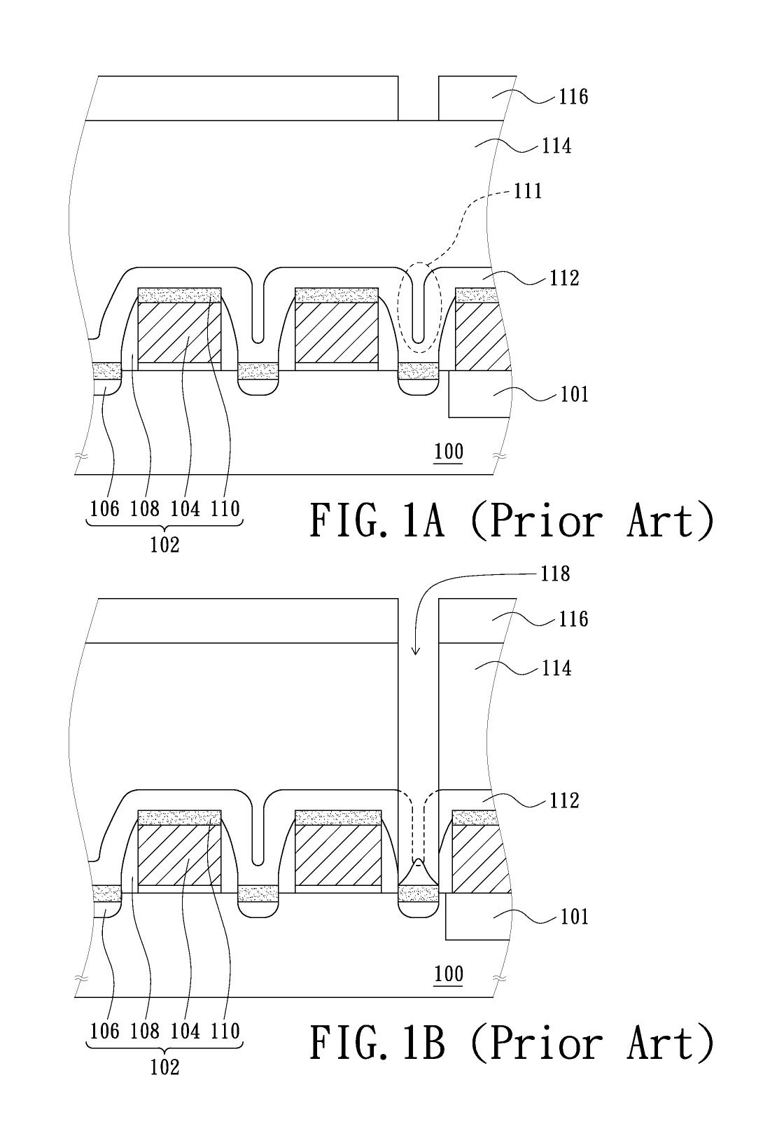

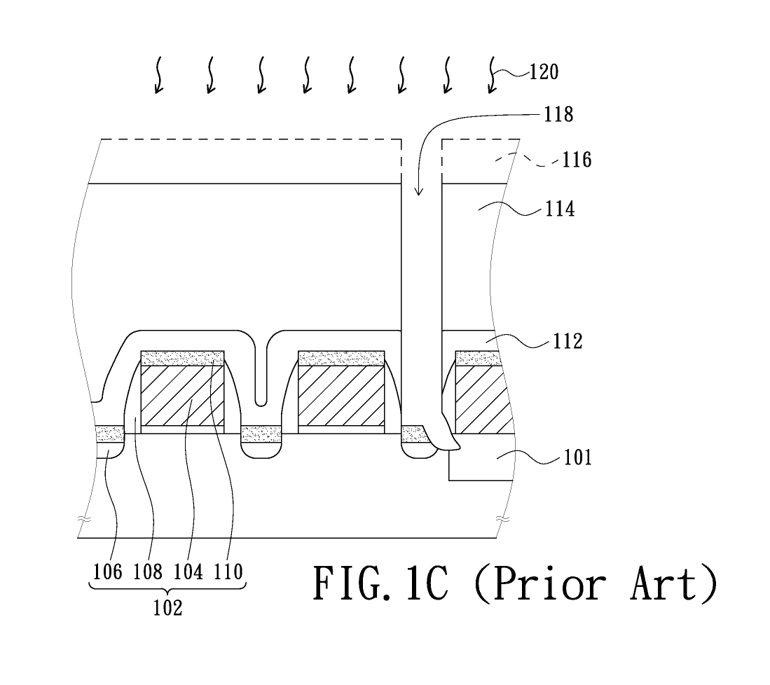

### DETAILED DESCRIPTION

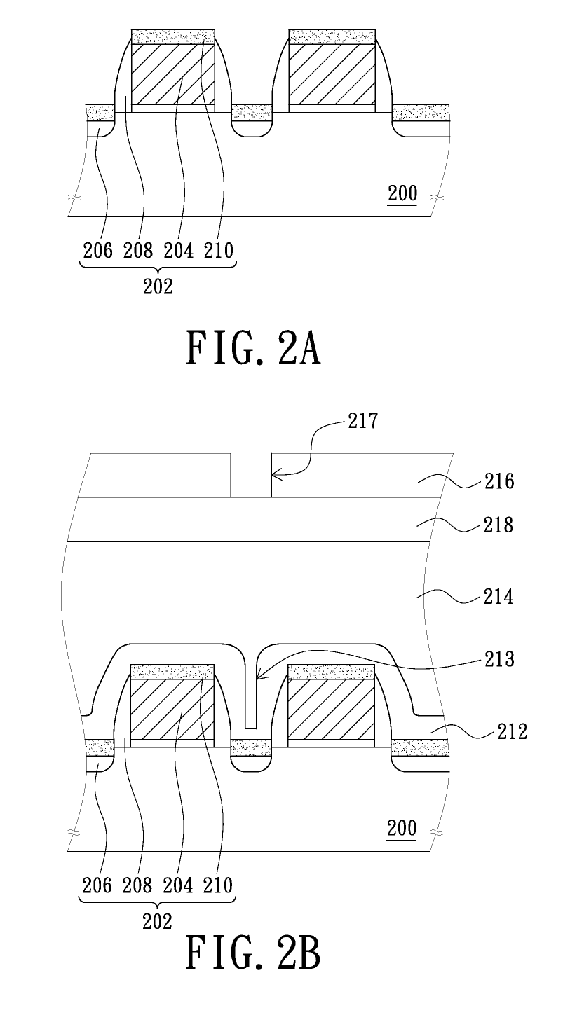

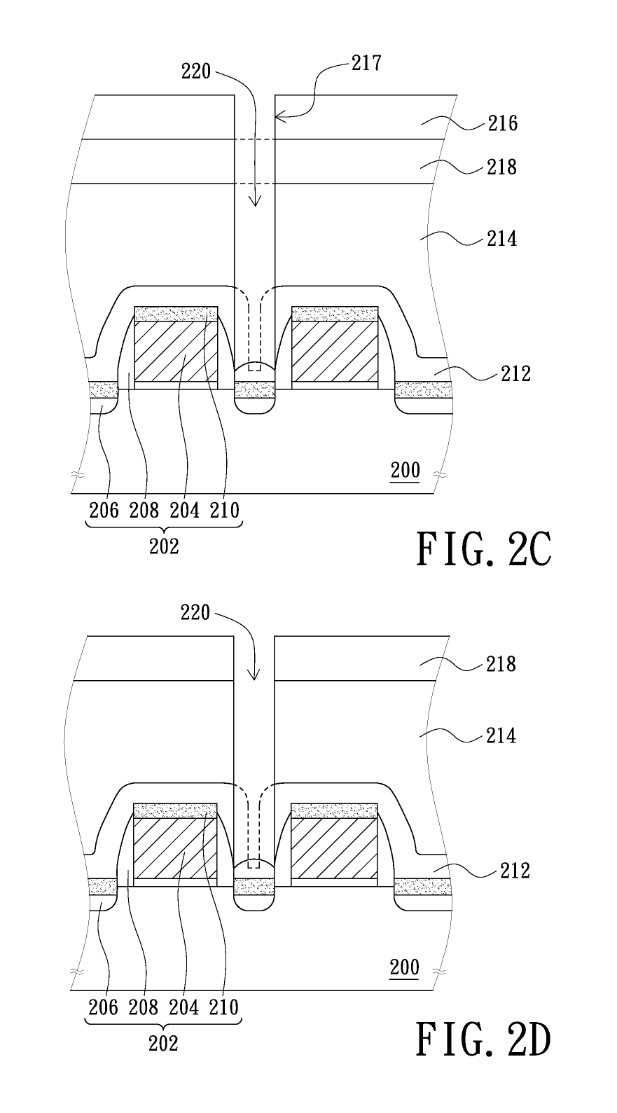

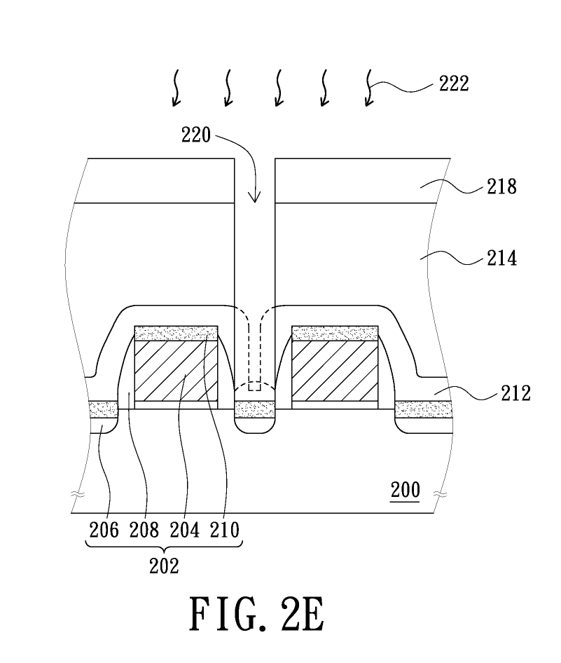

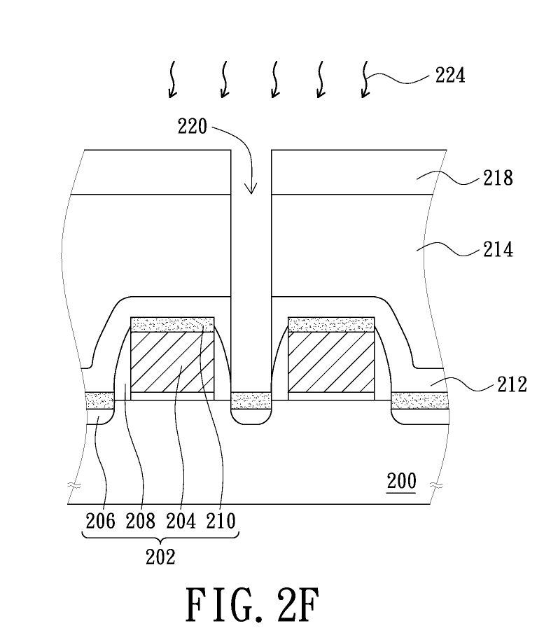

FIGS. 2A to 2F are cross-sectional schematic views of a contact opening at stages in a manufacturing process according to an embodiment of the present invention.

Referring to FIG. 2A, first, a plurality of semiconductor devices 202 are formed on a substrate 200. The substrate 200 can be silicon substrate, and an isolation structure (not shown) can be formed in the substrate 200. In the embodiment, each of the semiconductor devices 202 can be a transistor, which includes a gate 204, a source/drain region 206 and a spacer 208. In addition, a metal silicide layer 210 can be formed on the gate 204 and the source/drain region 206. Material of the metal silicide layer 210 can be cobalt silicide, titanium silicide, tungsten silicide, tantalum silicide, palladium silicide, platinum silicide, molybdenum silicide, nickel silicide or nickel alloy silicide. The nickel alloy silicide can be nickel platinum silicide, nickel cobalt silicide or nickel titanium silicide. The metal silicide layer 210 can be formed by a salicide process.

Next, referring to FIG. 2B, an etching stop layer 212 is formed on the substrate 200 to cover surfaces of the semiconductor device 202 and the substrate 200. Material of the etching stop layer 212 can be silicon nitride. The etching stop layer 212 may be formed by a chemical vapor deposition process. Because of design requirement of high integration, a merge phenomenon may arise in the etching stop layer 212 between the semiconductor device 202, and a gas 213 may formed in the merge position, and thus a portion of the etching stop layer 212 that is located between the semiconductor device 202 has a relatively larger thickness.

Next, a first dielectric layer 214 is formed on the etching stop layer 212. Material of the first dielectric layer 214 can be silicon oxide, silicate glass or material with a low dielectric constant. In addition, the first dielectric layer 214 can also be composed of an undoped silicate glass (USG) layer and a phosphosilicate glass (PSG) layer. The first dielectric layer 214 may be formed by a chemical vapor deposition process or a spin coating process. Next, a patterned photoresist layer 216 is formed on the first dielectric layer 214. The patterned photoresist layer 216 has an opening pattern 217 for forming the contact opening.

In an alternative embodiment, before forming the patterned photoresist layer 216, a second dielectric layer 218 can be formed on the first dielectric layer 214. Material of the second dielectric layer 218 can be silicon oxynitride. The second dielectric layer 218 may be formed by a plasma-enhanced chemical vapor deposition process. The second dielectric layer 218 can be used as a mask for etching to form the contact opening in the subsequent process.

Next, referring to FIG. 2C, layers that are not covered by the patterned photoresist layer 216 are removed to form an opening 220. The opening 220 is used as the contact opening. In detail, an etching process is performed by using the patterned photoresist layer 216 as the mask, so that a portion of the second dielectric layer 218 that is exposed by the opening pattern 217, and portions of the first dielectric layer 214 and the etching stop layer 212 that are located under the portion of the portion of the second dielectric layer 218, are removed to form the opening 220. In the embodiment, the etching process may be performed by a dry etching process.

Next, referring to FIG. 2D, the patterned photoresist layer 216 is removed after the opening 220 is formed. The patterned photoresist layer 216 may be removed by an oxygen plasma ashing process. Because the integration of the device is increased, portions of the etching stop layer 212 and the first dielectric layer 214 may remain at a bottom of the opening 220.

Subsequently, the layers that remain at the bottom of the opening 220 should be removed completely, so as to avoid affecting electrical property of the semiconductor and the reliability.

Next, referring to FIG. 2E, an over etching process 222 is performed to remove the layers remaining at the bottom of the opening 220, so as to expose the semiconductor device 202. In the embodiment, the opening 220 can expose the metal silicide layer 210 on the source/drain region 206 of the semiconductor device 202. In an alternative embodiment, the opening 220 can expose the metal silicide layer 210 on the gate 204 of the semiconductor device 202.

The over etching process 222 may be a dry etching process, which uses fluorine-containing hydrocarbons (CHₓF_{y}) and argon gas (Ar) as a main reactant gas. The fluorine-containing hydrocarbons can be selected from the group consisting of carbon tetrafluoride (CF₄), fluoroform (CHF₃), difluoromethane (CH₂F₂), methyl fluoride (CH₃F) and any suitable combination thereof. The argon gas may increase capacity of ion bombardment, so that polymer that is deposited on a sidewall of the opening 220 can be reduced. In addition, the reactant gas used in the over etching process 222 also includes hydrogen gas (H₂). The hydrogen gas is used to remove the polymer by-products generated in the etching process. In particularly, the over etching process 222 is performed in a nitrogen-free environment. In other words, the reactant gas used in the over etching process 222 does not include nitrogen gas.

The reactant gas used in the over etching process 222 includes the fluorine-containing hydrocarbons, the argon gas and the hydrogen gas. A flow rate of the fluorine-containing hydrocarbons can be in a range from 10˜30 sccm. A flow rate of the argon gas can be in a range from 600˜1000 sccm. A flow rate of the hydrogen gas can be in a range from 80˜200 sccm. Process pressure can be in a range from 30˜70 mT. Radio-frequency power can be in a range from 300˜800 W. Bias power can be in a range from 100˜500 W. In the embodiment, in the over etching process 222, the flow rate of the fluorine-containing hydrocarbons is 20 sccm, the flow rate of the argon gas is 800 sccm, the flow rate of the hydrogen gas is 100 sccm, the process pressure is 50 mT, and the radio-frequency power/bias power is 500/200 W respectively.

It should be pointed out that, in the over etching process 222, a speed of removing the polymer by-products by the hydrogen gas is smaller than that by the oxygen gas. Therefore, in comparison to the conventional over etching process, when the layers at the bottom of the opening are removed, following the method of the present invention a small quantity of the polymer by-products residue may remain at the bottom of the opening to protect the bottom of the opening and make etching rate of the layers uniform. Therefore, if the reactant gas used in the over etching process 222 includes the hydrogen gas, not only the polymer by-products can be removed, but also the spacer 208 and the metal silicide layer 210 of the semiconductor device 202 or the isolation structure can be prevented from being removed or damaged. In addition, the metal silicide layer 210 would not be oxidized, and thus the problem that electric property of the contact window is uncontrollable can be avoided.

Next, referring to FIG. 2F, a surface treatment process 224 is performed to clean the opening 220 in an in-situ mode by using a mixed gas, after performing the over etching process 222. The mixed gas can include nitrogen gas and hydrogen gas. A time used in the surface treatment process 224 can be 1 to 1.5 times of that used in the over etching process 222.

In the surface treatment process 224, a flow rate of the nitrogen gas can be in a range from 200˜400 sccm, a flow rate of the hydrogen gas can be in a range from 50˜400 sccm, pressure can be in a range from 150˜300 mT, radio-frequency power can be in a range from 300˜500 W, and bias power can be in a range from 50˜150 W. In the embodiment, the flow rate of the hydrogen gas is 300 sccm, the flow rate of the hydrogen gas is 100 sccm, the pressure is 250 mT, the radio-frequency power/bias power is 400/100 W respectively.

In other embodiments, if a thickness of the etching stop layer is increased according to the design requirement, there would be relatively more portions of the layers retained at the bottom of the opening 220 due to incomplete etching when the opening is formed. Therefore, after removing the patterned photoresist layer 216 and before performing the over etching process 222, a pre-etching process can be first performed in the nitrogen-free environment to remove a portion of the layers at the bottom of the opening. A reactant gas of the pre-etching process can include fluorine-containing hydrocarbons, oxygen gas and argon gas. The fluorine-containing hydrocarbons can be selected from the group consisting of carbon tetrafluoride, fluoroform, difluoromethane, methyl fluoride and any suitable combination thereof.

In the pre-etching process, a flow rate of the fluorine-containing hydrocarbons can be in a range from 10˜30 sccm. A flow rate of the argon gas can be in a range from 600˜1000 sccm. A flow rate of the oxygen gas can be in a range from 80˜200 sccm. Process pressure can be in a range from 30˜70 mT. Radio-frequency power can be in a range from 300˜800 W. Bias power can be in a range from 100˜500 W. In the embodiment, in the pre-etching process, the flow rate of the fluorine-containing hydrocarbons is 20 sccm, the flow rate of the argon gas is 270 sccm, the flow rate of the oxygen gas is 10.5 sccm, the process pressure is 30 mT, and the radio-frequency power/bias power is 1000/150 W respectively.

In summary, in the method for forming contact opening of the present invention, the reactant gas used in the over etching process includes hydrogen gas to substitute oxygen gas used in the conventional method. Therefore, not only the polymer by-products can be removed, but also the structures of the semiconductor device or the isolation structure can be prevented from being removed or damaged. In addition, the metal silicide layer would not be oxidized, and thus the problem that electric property of the contact window is uncontrollable can be avoided.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A method for forming contact opening, comprising:
forming a semiconductor device on a substrate;
forming an etching stop layer, a first dielectric layer and a patterned photoresist layer sequentially on the substrate;
removing a portion of the first dielectric layer and a portion of the etching stop layer to form an opening, the portion of the first dielectric layer and the portion of the etching stop layer being not covered by the patterned photoresist layer;
removing the patterned photoresist layer; and
performing an over etching process to remove the etching stop layer at a bottom of the opening and expose the semiconductor device in a nitrogen-free environment, a reactant gas of the over etching process comprising fluorine-containing hydrocarbons, hydrogen gas and argon gas.

2. The method for forming contact opening claimed in claim 1, wherein a surface treatment process is further performed to clean the opening by using a mixed gas, after performing the over etching process.

3. The method for forming contact opening claimed in claim 2, wherein the mixed gas comprises nitrogen gas and hydrogen gas.

4. The method for forming contact opening claimed in claim 3, wherein a flow rate of the nitrogen gas is larger than that of the hydrogen gas, in the mixed gas.

5. The method for forming contact opening claimed in claim 2, wherein a time used in the surface treatment process is 1 to 1.5 times of that used in the over etching process.

6. The method for forming contact opening claimed in claim 1, wherein the fluorine-containing hydrocarbons is selected from the group consisting of carbon tetrafluoride, fluoroform, difluoromethane, methyl fluoride and any combination thereof.

7. The method for forming contact opening claimed in claim 1, wherein after removing the patterned photoresist layer and before performing the over etching process, a pre-etching process is further performed in the nitrogen-free environment, and a reactant gas of the pre-etching process comprises fluorine-containing hydrocarbons, oxygen gas and argon gas.

8. The method for forming contact opening claimed in claim 7, wherein the fluorine-containing hydrocarbons is selected from the group consisting of carbon tetrafluoride, fluoroform, difluoromethane, methyl fluoride and any combination thereof.

9. The method for forming contact opening claimed in claim 1, wherein a second dielectric layer is formed on the first dielectric layer, before forming the patterned photoresist layer.

10. The method for forming contact opening claimed in claim 9, wherein material of the second dielectric layer comprises silicon oxynitride.

11. The method for forming contact opening claimed in claim 1, wherein material of the etching stop layer comprises silicon nitride.
